(19) United States
(12) Patent Application Publication
(10) Pub. No.: US 2023/0214690 A1
(43) Pub. Date: Jul. 6, 2023

(54) DATABASE SYSTEMS AND USER INTERFACES FOR PROCESSING DISCRETE DATA ITEMS WITH STATISTICAL MODELS ASSOCIATED WITH CONTINUOUS PROCESSES

(71) Applicant: Palantir Technologies Inc., Denver, CO (US)

(72) Inventors: Jeremy Elser, Philadelphia, PA (US); Andrew Floren, New York, NY (US); Aditya Naganath, New York, NY (US)

(21) Appl. No.: 18/182,240

(22) Filed: Mar. 10, 2023

Related U.S. Application Data
(63) Continuation of application No. 15/957,181, filed on Apr. 19, 2018.
(60) Provisional application No. 62/518,501, filed on Jun. 12, 2017.

(51) Int. Cl. G06N 5/04; G06N 20/00; G06F 30/20

(52) U.S. Cl. CPC G06N 5/04; G06N 20/00; G06F 30/20

(57) ABSTRACT

A computer-implemented method is provided to predict one or more expected quantities using a machine learning model. The method system may comprise steps to receive a set of data items associated with one or more characteristics, generate or train a machine learning model using the set of data items and associated characteristics, receive one or more sets of simulation parameters from a user indicating a hypothetical scenario and a time period, and generate user interface data. The user interface data may comprise a time-based chart illustrating the respective time periods. The computing system may further apply machine learning model to the set of simulation parameters to predict a set of expected quantities based on the simulation parameters, aggregate one or more types of expected quantities from the set of expected quantities to determine one or more combined quantities, and include in the user interface indications of the one or more combined quantities. The computing system may then cause the user interface to be presented. In some implementations of the method as disclosed herein, receiving the data items may comprise retrieving one or more discrete events from a data source, and converting the one or more discrete events into one or more continuous quantities.

### INCORPORATION BY REFERENCE TO ANY RELATED APPLICATIONS

This application is a continuation of the U.S. patent application Ser. No. 15/957,181, filed Apr. 19, 2018 which claims benefit of U.S. Provisional Patent Application No. 62/518,501, filed Jun. 12, 2017, and titled “DATABASE SYSTEMS AND USER INTERFACES FOR PROCESSING DISCRETE DATA ITEMS WITH STATISTICAL MODELS ASSOCIATED WITH CONTINUOUS PROCESSES.” The entire disclosure of each of the above items is hereby made part of this specification as if set forth fully herein and incorporated by reference for all purposes, for all that it contains.

Any and all applications for which a foreign or domestic priority claim is identified in the Application Data Sheet as filed with the present application are hereby incorporated by reference under 37 CFR 1.57 for all purposes and for all that they contain.

### TECHNICAL FIELD

Embodiments of the present disclosure relate to systems and techniques for accessing one or more databases and providing user interfaces for dynamic interactions with event data, creating models, such as machine-learning or statistical regression-based models, according to observed event data, conducting simulations and making predictions based on event data, performing retrospective analysis or cross-checking of observed results with model outputs, and conducting scheduling of future action based on existing events.

### BACKGROUND

Data, such as data related to events, may be electronically acquired from a variety of sources and may be stored for subsequent processing. Statistical inference and machine learning systems may seek to utilize stored data to infer a model of an underlying process or relationship.

### SUMMARY

The systems, methods, and devices described herein each have several aspects, no single one of which is solely responsible for its desirable attributes. Without limiting the scope of this disclosure, several non-limiting features will now be described briefly.

Embodiments of the present disclosure relate to systems and techniques for data collection and processing, including systems and techniques for accessing one or more databases in substantially real-time to provide information in an interactive user interface. More specifically, embodiments of the present disclosure relate to user interfaces for dynamically generating and displaying time varying complex data based on electronic collections of event data, scheduling simulations of events, retrospective analyses, or other types of processing related to event data, and creating schedules of future events based on data provided by the simulations.

Embodiments of the present disclosure relate to data processing, including database and file management, as well as a database system and database-related methods for dynamic and automated access of particular data sources and electronic data items, including event data. Embodiments of the present disclosure further relate to selective and efficient integration of electronic data items, including event data.

An embodiment may provide a computer-implemented service for data collection of various processes, quantitative measurements regarding various events may be collected. By using statistical regression and/or machine learning (e.g. modelling statistically independent events as Poisson distribution), comparisons may be made between different events, and variables related to the occurrence of certain types of events may be determined. These variables may then be further broken down or aggregated based on characteristics of the given event, such as time or location of occurrence of the event, environmental parameters related to a location or time of occurrence, and/or other parameters or characteristics of the event, such as an intensity, frequency or duration.

This may allow a user to process large datasets of observations related to events observed to ascertain key characteristics that affect or drive the occurrence of such events. Knowledge of these key characteristics can then be used to model, or simulate, the occurrence of similar events in the future, or provide aggregate data about the primary drivers or factors determining the occurrence of events. Visual, e.g. graphical, user interfaces may provide graphical representations, filtering, and effective presentation of the observed data, and results. Graphical user interfaces may further be utilized to provide visualization of data, e.g. display of events and aggregate data, and may provide interactive scheduling of simulations that estimate information regarding future events. Graphical user interfaces may also provide simple ways of performing optimization queries, wherein the system is queried to determine parameters that maximize the likelihood of a specific future event occurring.

In an embodiment, each event in the event data may be associated with retail sales of a product. Each event may correspond to a sale, and may be associated with additional information associated with the sale, such as the product, the product type, the product category, the sales price, the location (e.g. store) of the sale, the time and date of the sale, and any promotions associated with the location or product. For example, a given event may comprise data such as “Transaction Type: Sale; Date: 2016 Mar. 3; Time: 13:31 UTC; Product: HyperMega Ointment 12 ml; Price: 12.02 USD; Location: Store 1214; Promotions: 10% Mail-in Rebate”. Information related to events may also be binned or quantized; for example, sets of events may be associated with a given time period, such as a given day, reflecting finite accuracy of the acquisition of the information. For example, the date, time and location of sales in a given time period may be represented as an eventcount associated with a time interval, such as “From 2016-03-03; Time: 08:00 UTC; To 2016-03-03; Time: 18:00 UTC; Store 123; 15 Events” reflecting the fact that the event has occurred 15 times between 8 AM and 6 PM on the specified day.

Acquired data may comprise information related to various aspects, or dimensions, of observations, and dimensional data may make analysis and visualization difficult. Some statistical models or machine learning approaches may require event data in continuous or differential or flow quantities, while some event data may be most appropriately be collected as discrete quantities. For example, some events may inherently be distinct counts, instances or occurrences, such as delivery or sale of a product. Other events, while fundamentally continuous quantities (e.g. fluid flow), may be detected or processed on a discrete level; for example, fuel use of a vehicle may be continuous during operation, but may be difficult to be tracked as such, and thus may be accounted for on a continuous basis (e.g. based on individual refueling events). Embodiments may convert between continuous and differential or flow quantities to allow for models designed for continuous quantities (e.g. Poisson-distribution based statistical regression) to be used with discrete input quantities.

Embodiments of the present disclosure relate to systems and techniques for accessing data stores of event data and reduce, filter and visualize the information contained therein to efficiently provide information in an interactive user interface. Previous systems for display of, and interaction with, event data were typically inefficient at allowing the user to visualize information contained in the event data, and data provided by analysis of the system. Disclosed herein are systems that, according to various embodiments, advantageously provide highly efficient, intuitive, and rapid dynamic interaction with event data (including two-dimensional graphs and charts, including time-line representations, generated from observed event data and/or simulated event data) to enable the user to extract useful information, such as expected future parameters and aggregates, based on the events. The systems may include interactive user interfaces that are dynamically updated to provide rapid specification of parameters for simulations and other processing types related to event data, and scheduling of actual events based on the acquired information. Further, event data from multiple sources and/or time periods may be automatically sorted (e.g., in one embodiment, interleaved) by the system according to attributes associated with the images and rules and/or preferences of the user.

In an embodiment, the user may select a time period and/or category of events in the past, and the system automatically determines and displays aggregate event data from its historic event data store related to the time period and/or category selected. In an embodiment, the user may select a time period in the future and/or select appropriate parameters, and the system automatically queries its model, built based on historic event data, to determine expected aggregate event data for the future time period and/or the specified parameters. Time periods so selected and/or parameters specified may be displayed in an appropriate graphical user interface, such as a two-dimensional chart or time-line representation. Accordingly, a user may use the systems described herein to more quickly, thoroughly, and efficiently interact with time ranges associated with events, as compared to previous systems. The features and advantages noted above, as well as others, are discussed in further detail below.

Event Data may be acquired from a plurality of sources. Various electronic systems, such as electronic cash registers, servers, automated teller machines (ATMs), and other systems may automatically generate data associated with events processed through these systems. Other types of event data may be retrieved by dedicated measurement devices, such as motion detectors, satellite navigation receivers, etc. Still other types of Event Data may be acquired by manual observation, such as by a manual observer polling customers' sentiments upon leaving a store. Still other types of event data may be gathered through extraction from other types of record, whether traditional, such as paper records, or electronic records. For example, Event Data associated with commercial transactions may be acquired from a company's books or ledgers by appropriately processing out the data from these books and ledgers.

Event Data may be associated with a variety of other types of observations and measurements. For example, an Event related to a commercial transaction being performed may be associated with additional observations related to the amount, the parties, the time, the data, the location, and other relevant parameters associated with the transaction. It will be appreciated that by associating Events with such additional, or contextual, data, the set of events may become a multi-dimensional data fit, which may be difficult to visualize, process, and utilize. For example, typical data visualization software may be capable of plotting two dimensional and three dimensional data sets along two or three spatial dimensions. Where the data to be visualized has more than two or three dimensions, such software may not succeed in rendering a visualization unless all but two or three dimensions are discarded. It thus remains a need for visualization systems that can process and visualize event data having in excess of three dimensions.

The number of Events may, in some instances, be very large. In such instances, it may not be feasible to process all Events, unless appropriate computer algorithms are utilized to reduce, or model, or fit, the observed Event Data to a model comprising fewer degrees of freedom and/or lower complexity.

Various combinations of the above and below recited features, embodiments and aspects are also disclosed and contemplated by the present disclosure.

Additional embodiments of the disclosure are described below in reference to the appended claims, which may serve as an additional summary of the disclosure.

In various embodiments, systems and/or computer systems are disclosed that comprise a computer readable storage medium having program instructions embodied therewith, and one or more processors configured to execute the program instructions to cause the one or more processors to perform operations comprising one or more aspects of the above- and/or below-described embodiments (including one or more aspects of the appended claims).

In various embodiments, computer-implemented methods are disclosed in which, by one or more processors executing program instructions, one or more aspects of the above- and/or below-described embodiments (including one or more aspects of the appended claims) are implemented and/or performed.

In various embodiments, computer program products comprising a computer readable storage medium are disclosed, wherein the computer readable storage medium has program instructions embodied therewith, the program instructions executable by one or more processors to cause the one or more processors to perform operations comprising one or more aspects of the above- and/or below-described embodiments (including one or more aspects of the appended claims).

### BRIEF DESCRIPTION OF THE DRAWINGS

FIG. 1 is a block diagram illustrating an example processing system in an example operating environment.

FIG. 2 is a flow chart illustrating an example method of processing, acquiring, and visualizing event data, according to an embodiment of the present disclosure.

FIG. 3 is an illustration of an example processing system user interface displaying various event data items.

FIGS. 4A and 4B illustrate an example processing system user interface, presenting various predictions, and receiving inputs from various simulations, related to event data.

FIG. 5 illustrates an example processing system user interface, presenting event data visualized as a time series.

FIG. 6 illustrates an example input table as may be utilized by an example processing system.

FIG. 7 illustrates an example computer system, with which certain methods discussed herein may be implemented.

### DETAILED DESCRIPTION

Although certain preferred embodiments and examples are disclosed below, inventive subject matter extends beyond the specifically disclosed embodiments to other alternative embodiments and/or uses and to modifications and equivalents thereof. Thus, the scope of the claims appended hereto is not limited by any of the particular embodiments described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain embodiments; however, the order of description should not be construed to imply that these operations are order dependent. Additionally, the structures, systems, and/or devices described herein may be embodied as integrated components or as separate components. For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein.

### Overview

Embodiments of the disclosure will now be described with reference to the accompanying figures, wherein like numerals refer to like elements throughout. The terminology used in the description presented herein is not intended to be interpreted in any limited or restrictive manner, simply because it is being utilized in conjunction with a detailed description of certain specific embodiments of the disclosure. Furthermore, embodiments of the disclosure may include several novel features, no single one of which is solely responsible for its desirable attributes or which is essential to practicing the embodiments of the disclosure herein described.

### Terms

User Input (also referred to as “Input”): Any interaction, data, indication, etc., received by the system from a user, a representative of a user, an entity associated with a user, and/or any other entity. Inputs may include any interactions that are intended to be received and/or stored by the system; to cause the system to access and/or store data items; to cause the system to analyze, integrate, and/or otherwise use data items; to cause the system to update to data that is displayed; to cause the system to update a way that data is displayed; and/or the like. Non-limiting examples of user inputs include keyboard inputs, mouse inputs, digital pen inputs, voice inputs, finger touch inputs (e.g., via touch sensitive display), gesture inputs (e.g., hand movements, finger movements, arm movements, movements of any other appendage, and/or body movements), and/or the like. Additionally, user inputs to the system may include inputs via tools and/or other objects manipulated by the user. For example, the user may move an object, such as a tool, stylus, or wand, to provide inputs. Further, user inputs may include motion, position, rotation, angle, alignment, orientation, configuration (e.g., fist, hand flat, one finger extended, etc.), and/or the like. For example, user inputs may comprise a position, orientation, and/or motion of a hand or other appendage, a body, a 3D mouse, and/or the like.

Data Store: Any computer readable storage medium and/or device (or collection of data storage mediums and/or devices). Examples of data stores include, but are not limited to, optical disks (e.g., CD-ROM, DVD-ROM, etc.), magnetic disks (e.g., hard disks, floppy disks, etc.), memory circuits (e.g., solid state drives, random-access memory (RAM), etc.), and/or the like. Another example of a data store is a hosted storage environment that includes a collection of physical data storage devices that may be remotely accessible and may be rapidly provisioned as needed (commonly referred to as “cloud” storage).

Database: Any data structure (and/or combinations of multiple data structures) for storing and/or organizing data, including, but not limited to, relational databases (e.g., Oracle databases, mySQL databases, etc.), non-relational databases (e.g., NoSQL databases, etc.), in-memory databases, spreadsheets, as comma separated values (CSV) files, eXtendible markup language (XML) files, TeXT (TXT) files, flat files, spreadsheet files, and/or any other widely used or proprietary format for data storage. Databases are typically stored in one or more data stores. Accordingly, each database referred to herein (e.g., in the description herein and/or the figures of the present application) is to be understood as being stored in one or more data stores.

Event: An occurrence or transaction associated with a point or span in time. For example, an event may be a measurement of a physical quantity, such as a temperature at a given point in time, a commercial transaction, such as a sale or a purchase, or any other type of occurrence that is associated with time.

Event Data: Various observations, measurements, other events, and other types of data may be associated with an event. For example, in a situation where an event represents a commercial transaction, such additional data may comprise the price, the type of good, and whether the transaction was a sale or purchase.

### Example Computing Devices and Systems

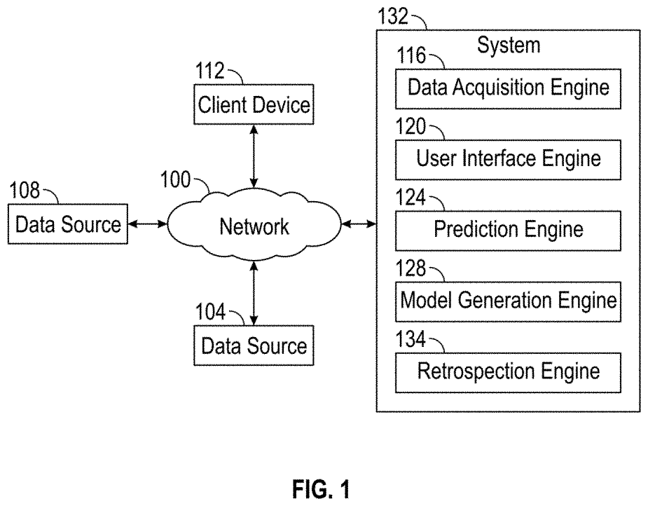

FIG. 1 illustrates an example processing system 132 in an example operational environment. Example processing system 132 may consist of a data acquisition engine 116, a user interface engine 120, a prediction engine 124, a model generation engine 128, and a retrospection engine 134. The components of processing system 132 may be interconnected by a variety of means, such as network connections, shared memory, named or anonymous pipes, etc, and may thus interact with each other. System 132 may be connected, for example via network 100, to one or more data sources, such as data source 104, and data source 108, and one or more client devices, such as client device 112. Network 100 may be any type of data network, such as, for example, the Internet, and Ethernet network, or a WiFi. Connections between these components enable each component to operate upon data contained in and/or results produced by the other components.

Data sources 104 and 108 may be type of automated, manual or semi-automated sources of information, such as event information. For example, data source 104 and/or data source 108 may be any combination of a data logger, a server, an electronic register, an automated teller machine, or any other type of device that can record or gather data related to events. Data acquisition engine 116 may call, for example, via network 100, the data sources, such as data source 108 and data source 104, so as to acquire and store the data provided by the data sources.

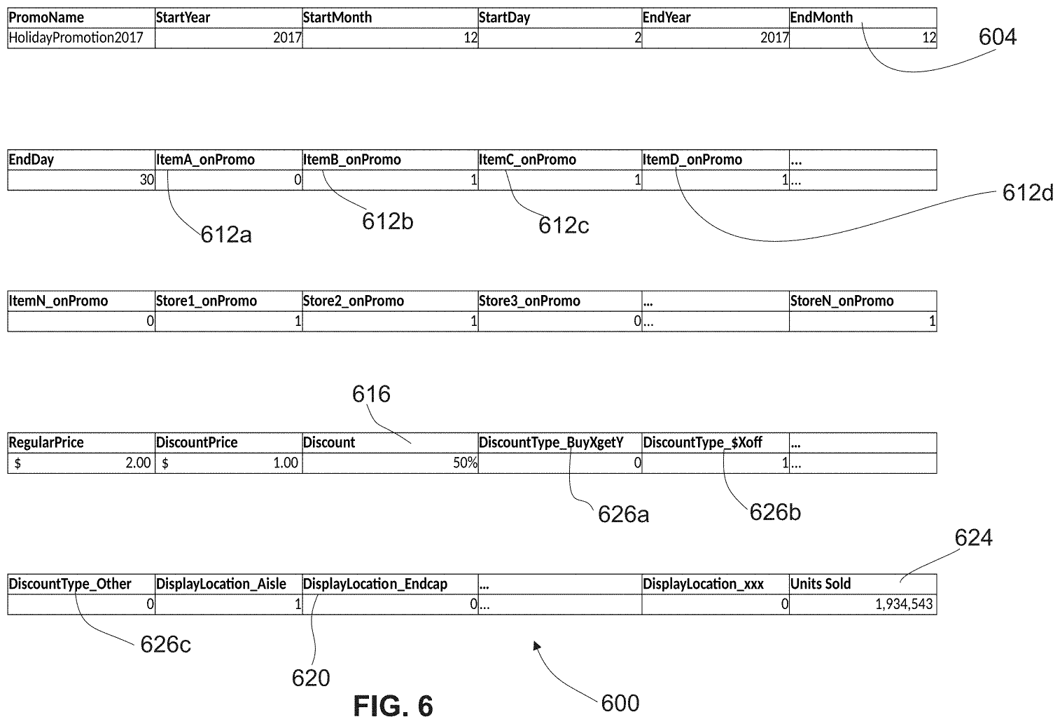

Data acquisition engine 116 may make the data from the data sources available for further processing and analysis, for example by normalizing or transforming them into a canonical form, and storing them in a database, such as a relational database. For example, data acquisition engine 116 may receive data from data source 104, and may transform or normalize the received data, for example as discussed with reference to FIG. 6 herein. Data acquisition engine 116 may then store the data received in a table associated with data source 104 in a relational database. Event data may comprise various pieces of information associated with an event or occurrence, such as the type of event, a time or date of the event, other parameters or environmental observations, such as an amount, a location or a person or category associated with a transaction. In particular, various pieces of information may be associated with the event that may conceivably affect the occurrence of the event; for example, where the event is associated with the failure of a piece of machinery, additional data acquired may be the temperature of the machinery, the load or output of the machinery, etc. As an additional example, where the event is associated with a commercial transaction, additional data acquired may be the location where the transaction was entered, the cost and quantity of the transaction, and any deviations from the typical terms and conditions of similar transactions (e.g. discounts). As yet another example, environmental parameters at the time and location of the event, such as altitude, temperature, meteorological conditions, etc., may be associated with the event.

The data so acquired may then be used by other components of system 132, such as the model generation engine 128. For some types of events, it may be advantageous to collect this additional data at the time of occurrence; for example, in the event of a commercial transaction, gather the location and terms of the transaction at the same time that the event is occurring. For other types of events, this data may be supplemented at a later point in time, e.g. from external sources, during subsequent analysis.

The model generation engine 128 may process and analyze the data received from data sources, such as data source 104, to determine a statistical model, and/or a machine learning model, that may be used to explain the observed data. Model generation engine 128 may then store the parameters of this model in a database, so that other components of system 132 may access and utilize it. Specifically, system 132 may comprise a prediction engine 124 and/or a retrospection engine 134 that may utilize, or query, the statistical or machine-learning model determined by model generation engine 128.

Prediction engine 124 may use a statistical model and/or a machine learning model, such as the model created by model generation engine 128 to determine estimates of data associated with future events. Prediction engine 124 may receive, for example, from a user, information related to scenarios or external variables, associated with a particular scenario. The prediction engine 124 may then utilize the model generated by model generation engine 128, to determine an expected result or an expected observation based on the model. Retrospection engine 134 may also utilize the model generated by model generation engine 128 to determine an extent to which the model generated by model generation engine 128 agrees with, or is compatible with, a specified observation or set of observations.

System 132 may interact with a user through user interface engine 120. User interface engine 120 may be, for example, a web server, that accepts connections from a client device, such as client device 112, via network 100. User interface engine 120 may receive data from client device 112, and may store and/or forward it to the various other components of system 132. User interface engine 120 may also receive information from the other components of system 132, and send it, or present it, to the user through client device 112. Client device 112 may, for example, be a user's desktop computer, smartphone, or other type of computing device and associated software, e.g. a browser capable of rendering visual output from user interface engine 120's user interface data.

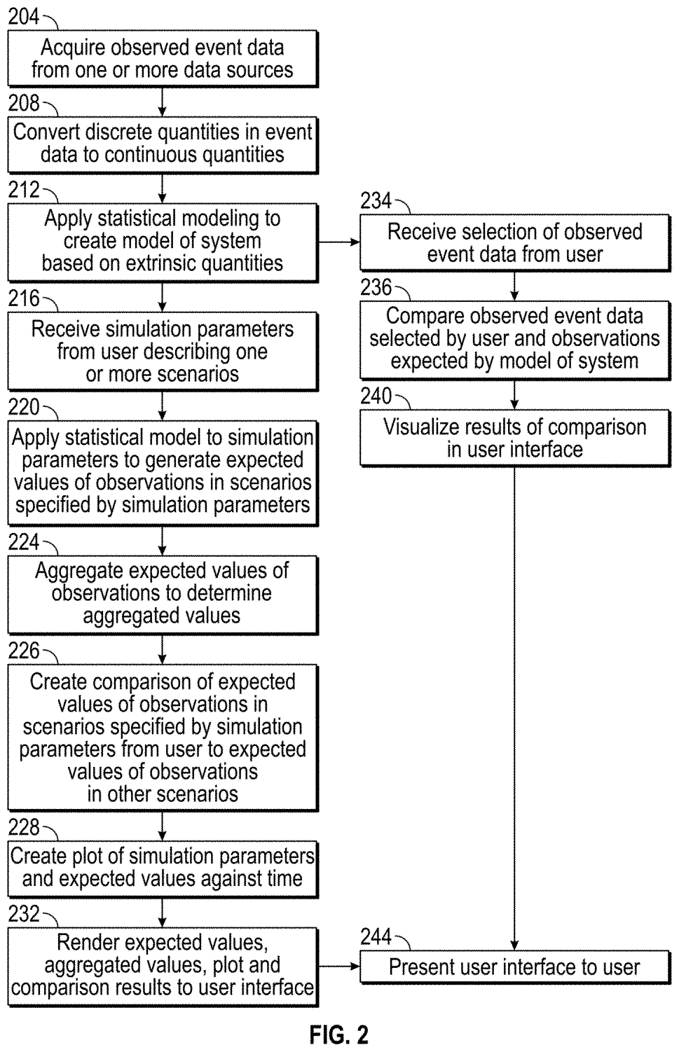

FIG. 2 shows a flow diagram depicting illustrative client-side operations of the system, according to an embodiment of the present disclosure.

In block 204, data, such as observed data associated with one or more events, is acquired from one or more data sources. The data may be acquired by data acquisition engine 116 accessing data sources, such as data source 104, through a network 100. For example, block 204 may be executed as a regularly scheduled data acquisition step, wherein data acquisition engine 116 connects or polls data source 104 in regularly scheduled intervals to receive new event data.

In block 208, discrete quantities, as may have been acquired from the one or more data sources in block 204, may be converted to continuous quantities and/or otherwise converted to a canonical or normalized form. In some instances, data sources, such as data source 104, may, by design, output discrete quantities, whereas for subsequent processing, continuous or flow quantities may be more convenient. For example, if data source 104 logs an event for every transaction that it processes, this data may be converted into a continuous quantity, such as a rate quantity (e.g. the number of transactions per minute, per hour, per day, or other appropriate interval), or a durational quantity (e.g. the time between transactions, such as minutes between transactions, hours between transactions, days between transactions, etc.).

Additionally, some quantities acquired from the one or more data sources in block 204 may be transformed or re-encoded from a categorical representation or a flag or bit-field representation to a canonical form, as discussed further with respect to FIG. 6. For example, For some observations or data items on which statistical regression is to be performed by model generation engine 128, the representation of the data may be converted or changed to better fit the statistical model used. This may include converting packed data representations (e.g. categorical or bit-field representations of data) to a list of values (e.g. true-false or Boolean values).

Appropriate intervals may be chosen based on the frequency of events to allow for sufficient granularity of the analysis on one hand without unduly introducing discretization error. The choice of granularity in Block 208 may be seen as a trade-off between resolution of the resulting analysis and statistical error.

Various methods known in the art for determining the granularity, such as fitting the event data to a statistical distribution, e.g. a Poisson distribution, and choosing a granularity that minimizes a quantity of the resulting distribution, such as minimizing Mean Integrated Squared Error (MISE), may be used. A method for selecting the granularity is disclosed in Shimazaki H. and Shinomoto S., A method for selecting the bin size of a time histogram Neural Computation (2007) Vol. 19(6), 1503-1527, which is incorporated by reference. Block 208 may comprise averaging, such as, for example, time averaging, to convert the discrete quantities into continuous quantities, based on the granularity chosen. Alternatively, the granularity may be chosen based on a constant factor, such as, for example, weekly, bi-weekly or monthly intervals. A table structure (e.g. a schema of a table represented in a relational database system) associating product sales with a time and location may, for example, be structured in item-store-day format. The table may comprise, for example, for each day that a given store was open, a column indicating the day, the average price the product was sold, the units of products sold, and a value indicating whether or how that product was being promoted that day.

Advantageously, this may allow the use of statistical methods and models that rely on input data being continuously distributed; for example, discrete sales events may be utilized to fit or approximate the “rate” parameter of a Poisson distribution.

In block 212, statistical regression and/or machine learning may be used by model generation engine 128 to create a model of the system to which the observed event data pertains, based on the event data observed and the associated extrinsic quantities.

Various statistical modeling or inference, and/or machine learning methods known in the art may be used. For example, various one- or more-parametric statistical distributions may be fitted to the event data. For example, events may be presumed to occur at a time-dependent a time-dependent or periodic (e.g. seasonal, or monthly) rate k, in which case the event data (now represented as continuous or flow quantities) may be fitted to a Poisson distribution. Alternatively, other distributions (e.g. normal distribution; geometric distribution) may be used as appropriate. Events may also be presumed to occur on a rate that depends on time, as well as one or more extrinsic variables associated with the event. For example, rate λ may be dependent on both the time (e.g. seasonal periodicity) as well as another extrinsic variable, such as the location or other parameters associated with the event. In such situations, rate λ may be considered to be a function λ(t, x,y,z), wherein t represents a variable periodic in time, and x, y, z represent other parameters associated with the event. The exact form of function λ(t, x,y,z) may be dependent on the nature of the event and may reflect certain assumption; for example, where x, y and z are deemed to independently contribute to the overall rate λ, λ(t, x,y,z) may be written as:

λ(t,x,y,z)=T*t+X*x+Y*y+Z*z

The system may then utilize appropriate multi-variate linear or non-linear regression techniques (e.g. Generalized Linear Model regression) to determine appropriate values for the regression parameters; in the example, the regression parameters are T, λ, Y and Z, and may be simultaneously determined based on the event data.

In an embodiment, the system may further use statistical techniques known in the art, such as principal component analysis, to further reduce the number of variables in the model, and/or to determine which parameters are the most relevant, and/or to identify parameters which may be removed from the model without significantly impacting its fit to the data.

Alternatively, instead of utilizing an explicit statistical regression type model, as discussed above, machine learning methods, including unsupervised learning methods, may be utilized. For example, it may not always be possible to determine a relationship between various parameters associated with the event and the rate at which events occur, or such a relationship may be may be difficult to express in analytical form. In an embodiment, machine learning algorithms, such as generalized linear models, neural networks, decision trees, random forests, or support vector machines, may be utilized. Numerical rounding or other binning techniques may be applied to the supervisory variable to create a categorical supervisory variable (e.g. profitable vs unprofitable) such that classifier algorithms can be substituted for regression models. The machine learning model may be created from, or trained, onto the event data, or a subset thereof; in an embodiment, the event data may be split into two partitions, wherein one partition is used as the “training” dataset for the machine learning algorithm and another partition is used as a “test” dataset to determine the accuracy of the resulting model. Advantageously, this may be used to quantify the expected error in the model and/or reduce overfitting.

In one of blocks 216 and block 234, the system receives a request from a user. The system may offer the user to send different types of requests, corresponding to different queries to be performed by the system. If the user submits a set of simulation parameters, the system may proceed with block 216. Conversely, if the user submits a selection of observed event data, the system may proceed with block 234. This may allow the system to service different types of information requests from the user.

In block 216, a set of simulation parameters is received from the user and stored to facilitate querying the statistical or machine-learning model as determined in block 212. These simulation parameters may correspond to one or more items of information associated with an event or occurrence, such as the type of event, a time or date of the event, other parameters or environmental observations, such as an amount, a location or a person or category associated with an event associated with a transaction. The system may fill in or supplement parameters not specified by the user; for example, the system may fill in such unspecified parameters by determining a value corresponding to an average from past events. For example, the user may specify a certain time in the future and a certain location, but may leave other environmental parameters unspecified. The system may then determine a historical average, minimum, maximum or other aggregate of the unspecified values.

In block 220, the simulation parameters received from the user, filled in or supplemented as appropriate, may be applied to the statistical model or machine-learning model, to generate an expected value of observations in a scenario as specified by the simulation parameters. This may be visualized as the system asking and answering the question of what observations would be expected in a scenario specified by the simulation parameters from the user, based on the statistical model determined in block 212. In an embodiment, for each set of simulation parameters specified, more than one simulation may be performed; for example, one simulation may be performed to determine an expected outcome if a scenario at a given time and as specified in the simulation parameters is realized, while another simulation is performed to determine an expected outcome at the given time if the scenario is not realized. This may establish a “baseline” to compare contemplated action against.

In block 224, the values, such as expected values, determined from querying the statistical model or machine-learning model with the simulation parameters, may be aggregated or combined. For example, the model may generate averages, minima, maxima, medians and other combinations of the expected values.

In block 226, the expected values as determined in block 220, and/or the aggregates as determined in block 224 may be compared amongst each other. For example, the system may determine a rise of an expected occurrence of an event rate or other expected quantity over a given baseline (a “lift”).

In block 228, a chart or graph of the simulation parameters, and the expected values associated with them, may be created. The chart or graph may be, for example, a two-dimensional timeline view, wherein one axis corresponds to time, and the other axis corresponds to some or all of the various simulation parameters or scenarios specified. The chart or graph may be color-coded or symbol-coded, e.g. each entry or time period may be associated with a color or symbol indicating a type of scenario.

In block 232, a user interface may be generated. The user interface may be a graphical user interface and may comprise various elements, as illustrated herein, including the expected values as determined in block 220, the aggregated values as determined in block 224,

In block 234, a selection of observed event data is received from a user. The user may, for example, specify one or more time ranges, sets of events, or other selection.

In block 236, the statistical model or machine learning may be queried based on the selection of observed event data to determine one or more expected values based on parameters associated with the selected events. These parameters may, for example, be associated with certain conditions or characteristics; for example, the user may specify promotions, such as a contemplated type of rebate or advertising campaign. The statistical model or machine learning model may then be queried based on these parameters specified; for example, the model may be queried to determine what type of events or associated quantities would be expected if the specified parameters (e.g. the specified type of advertising campaign) were implemented. This querying of the statistical or machine learning model be implemented by retrospection engine 134. Additionally or alternatively, retrospection engine 134 may utilize the event data in its discrete for, e.g. as acquired in block 204. For example, retrospection engine 204 may utilize clustering or dimensionality reduction methods, such as principal component analysis (PCA), to determine whether the observed events are within a certain region bounded by, or centered around, the discrete events. For example, retrospection engine 204 may determine the average distance, median distance, or nearest-neighbor (e.g. minimum) from an observed to the closest observed event, or a cross-correlation between observed and existing data points. Advantageously, this may allow to determine discrepancies between the observed events and the observed data more accurately than only relying on the continuous representation of the observed events; particularly, this may allow the system to surface certain types of erroneous or fabricated data. For example, if observed event data collected during some time periods is reliable, but event data collected during other time periods is a mere duplication of the event data during such other time periods, this type of error during data collection could be rapidly detected by retrospection engine 204 calculating a cross-correlation or distance between observed event data and existing historic data in the system.

In block 240, a user interface may be generated to visualize the result of the comparison. For example, the user interface may indicate a measure of agreement or conformity between the model and the observed value; such value may be considered a discrepancy or deviation from the statistical or machine-learning model. Advantageously, such comparison may allow the statistical model to be verified or “ground-truthed”, or may allow for event data to be checked for plausibility. This may be implemented by first determining a statistical distribution for the observed value based on the statistical or machine-learning model, and then determining a likelihood based on which the observed value appears to be randomly drawn from the distribution. For example, the observed value may be assumed to be Poisson-distributed, and the rate parameter for the Poisson distribution may be read off from the statistical or machine-learning model. The observed values may then be compared to the distribution through a variety of statistical tests, such as a chi-squared goodness of fit test appropriate to the statistical distribution used. The resulting value may be a probability indicating how well the observed values follow the expected distribution. By comparing this value to a threshold value, such as, e.g. 95%, the system may determine whether a significant deviation between the observed values and the distribution exists. Such comparison, may, for example, allow the user to determine a likelihood of whether a store has indeed executed a certain sales promotion based on an agreement between the sales data from the store to the sales data of other store. The output of the system may be a conformity calculated as a likelihood, e.g. a percentage value, p-value or sigma value, indicating an estimate how likely the observed data appears to be drawn from a statistical distribution as represented by the model. For example, a value of 80% may indicate an estimate by the system that, if 80 out of 100 randomly drawn samples from the distribution reflected by the statistical or machine-learning model would match the statistical or machine-learning model as good or better than the data given; conversely, 20 out of 100 such samples would not. This may allow to determine systematic deviations; for example, if a given store had not executed a promotion, the conformity between the model output for the observations under the given parameters (reflecting the assumption that a promotion was executed) and reality (with no promotion having been executed) may be expected to be statistically significantly low.

In block 244, the user interfaces generated in blocks 232 and 240 may be presented to the user. Block 244 may be implemented by user interface engine 120. For example, block 244 may comprise sending an HTML document to a web browser by a user.

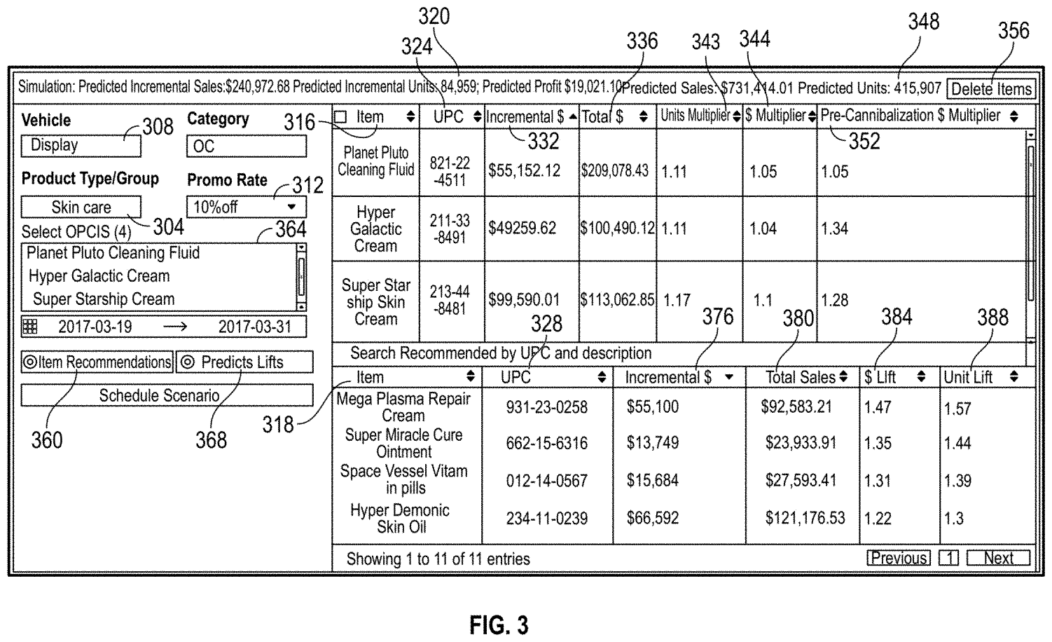

FIG. 3 illustrates an example user interface, as may be presented by user interface engine 120 in block 244 related to prediction of events and associated quantities. Selection boxes 304 and 364 allow the user to determine a type of event category and/or parameters associated with various events. In the illustrated embodiment, events are associated with sales of various retail products, so the selection boxes may be associated with various product types (selection box 304) and product name (selection box 364). Selection boxes 308 and 312 may allow the user to specific various external parameters, such as a promotion campaign (selection box 308) and a price discount (selection box 312) which may be used for simulating, and/or subsequently scheduling, a promotion.

Based on these selections, the selection of all events (e.g. all products sold) can be filtered down to certain interesting regions (e.g., as illustrated, certain products of type “skin care”, sold between 2017-03-19 and 2017-03-31), and/or a simulated or scheduled promotion can be placed in such time region.

By selecting button 368, a simulation with the parameters specified in selection boxes 308 and 312 can be started as discussed with reference to blocks 216, 220, 224 and 226. As illustrated, the system may calculate “lifts”, or expected aggregate change, in unit quantity and revenue. As discussed, the calculation of “lifts” may comprise prediction engine 124 performing a query on the statistical or machine-learning model associated with the promotion described in selection box 312 and time frame specified in selection box 364, and another query associated with the same timeframe but not associated with the promotion. Comparing the outputs from the two simulation may allow the system to determine a difference between the outputs from the two simulations, and calculate an expected lift from the difference.

By selecting button 360, the system may perform simulations based on the specified parameters on all products selected in selection box 364 and sort by the resulting lifts. This may allow the machine to automatically try out various sets of parameters in simulations subject to user defined constraints. This may save the user the effort of having to exhaustively manually search the possible parameter space of all promotions. Advantageously, this may allow the system to find or recommend those items on which, based on the given machine learning model, a promotion would be most effective. The products chosen by the system, and associated quantities, may be displayed in table format; as illustrated, columns 318 gives the name of the recommended product, 328 the associated product code, column 376 the expected incremental sales, column 380 the expected total sales, column 384 the expected dollar lift, and column 388 the expected unit lift, if the scenario associated with the parameters specified in selection boxes 308 and 312 were realized. Again, the expected lifts may be calculated by comparing the output from a simulation comprising the specified promotion parameters with the output from another simulation, associated with the same timeframe, but not associated with a promotion.

Columns 316, 324, 332, 336, 344 and 352 illustrate various data as observed, as predicted by the statistical or machine-learning model, or a comparison of both. Column 316 gives the name of the product and column 324 gives the associated product code; column 332 shows an incremental sales amount, and column 336 shows a total sales amount, if the scenario associated with the parameters specified in selection boxes 308 and 312 were realized. Column 343, 344 and 352 show ratios to allow relative comparison between the scenario and the alternative. Particularly, column 344 takes into account that if the scenario is realized as to one or more category of events, other categories of events may be affected. For example, in the illustrated scenario, if a promotion of one type of product is commenced, some of the expected additional sales may be at the expense of another product in the same category (“cannibalization”). By running the simulation of other products under the assumption that a given product is discounted, the system may estimate this cannibalization. As such, column 344 shows the expected multiplier including an estimate of the net incremental sales including the cannibalization effect, whereas column 352 excludes the effect. Column 343 indicates a “unit lift” ratio, or the relative change in units sold. Advantageously, by comparing values in column 343 with column 344, two potential failure scenarios of a promotion may be identified: A weak promotion that will generate low dollar lift due to failure to generate incremental purchases will be characterized by a low value in column 343, whereas a weak promo that will generate many more purchases but at too steep a price discount to generate revenue may be characterized by a low (below 1) value in column 344.

Button 356 allows the user to delete items from the list of events, so as to exclude them from further processing. By selecting one of columns 316, 324, 332, 336, 344 and 352, the user may cause the system to sort the table by the value associated with the selected column. Advantageously, the user may thus sort the table by, for example, sort by columns 336, 344, and 352, review the bottom or lowest-performing entries in the sorted table, and subsequently use button 356 to delete the lowest-performing entries.

In row 320, various aggregates as determined from querying the statistical model and comparing the resulting data with observed quantities, are displayed. For example, the system may show the expected increase in events (e.g. sales), the expected increase in revenue, and a predicted profit, if the situation corresponding to parameters specified in selection boxes 308 and 312 were realized.

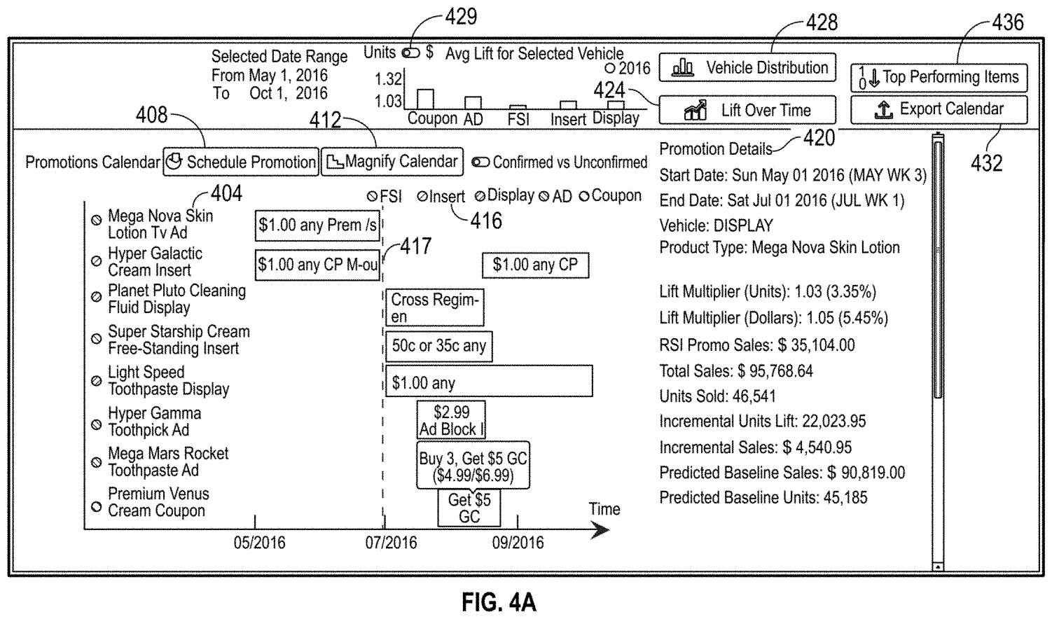

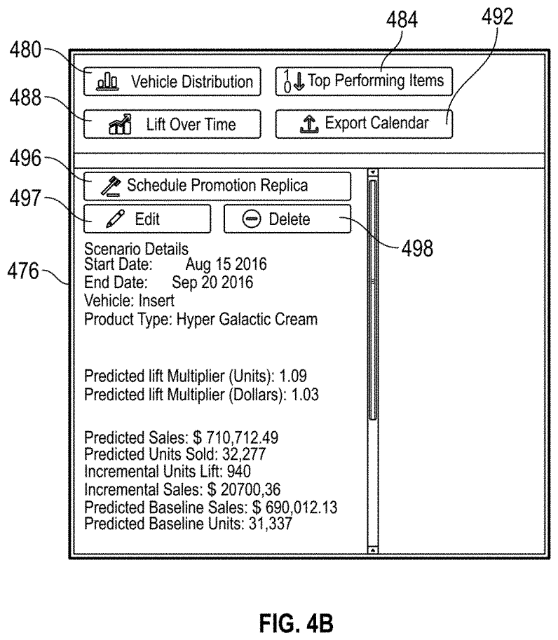

FIGS. 4A and 4B illustrates an example user interface, as may be presented by user interface engine 120 in block 244, related to prediction of events and associated quantities, and scheduling of events. Timeline 404 illustrates a list of event types, corresponding to different products, and associated parameters, corresponding to different promotion campaigns. For example, product “Mega Nova Skin Lotion” is scheduled to be promoted by a $1.00 discount promotion with a TV ad. The horizontal extent of each block, corresponding to each product, illustrates the time period during which the promotion is scheduled to be performed. Each block may be selected, for example by the user clicking it in the user interface, to bring up additional detail. A selected block may be shown shaded to indicate that it is selected. Indicator 417 indicates the current date in the timeline, based on the system's real-time clock.

Column 420 illustrates additional details about a selected promotion, such as an expected start date, end date, predicted lift in units, predicted lift in dollars, predicted total sales, predicted total unit sold, predicted baseline sales during the period in question, etc. The system may automatically determine the appropriate method—prediction or retrospection—based on whether the selected promotion is in the past or in the future. If the promotion is in the past and data is already available, the system will utilize retrospection engine 134 to estimate the effectiveness of the promotion based on comparing the observed event data (e.g. sales proceeds and units sold) with a results from the statistical or machine learning model for a hypothetical scenario where there was no promotion during the timeframe. If the selected promotion is in the future, or there is no data related to the selected promotion, the system will utilize prediction engine 124 to query the statistical or machine learning model to predict expected values, such as sales proceeds and units sold, if the promotion takes place, and if the promotion does not take place. It will be appreciated that by using actual data where such data is available, and automatically substituting data from the statistical or machine learning model where such data is not available, errors introduced by the statistical or machine learning model's failure to accurately predict reality may be reduced.

For example, information in column 420 illustrates data related to a promotion in the past; as such, some observed data related to the time period in question is already available and is utilized by the system. The system can thus calculate some quantities, e.g. “total sales”, on the basis of observed data, and compare the observed quantities to expected data determined for the hypothetical scenario where there was no promotion. Conversely, FIG. 4B illustrates an interface describing a promotion scheduled for the future, for which observed data is thus not available yet. Column 476 yields substantially similar information to column 420, but the system's output is a prediction, so the quantities are described as “estimated”.

It will be appreciated that the information presented in column 476 may thus be determined from one or several simulation runs with different parameters; for example, the system may run one simulation of the statistical model or machine-learning model with “baseline”, or parameters corresponding to the absence of a promotion, and run another simulation with parameters corresponding to a promotion as specified in timeline 404. It will further be appreciated that by presenting past promotions and future promotions in the same or a similar interface, and by dynamically choosing between observed and simulated data, the user is advantageously able to access both historic data and predictions with minimal duplicative effort and efficiently.

Buttons 496, 497 and 498 relate to manipulating the scheduled promotion for the future. Advantageously, these buttons may be hidden where the promotion has occurred in the past, since editing or deleting a promotion is only possible for future events. By selecting button 496, the user may be able to schedule a similar promotion for another point in the future. By selecting button 497, the user may edit the promotion, e.g. the promotion parameters, such as the product type or discount amount. By selecting button 498, the user may cancel the scheduled promotion. The user can thus save time in creating new scenarios by selecting relevant historical scenarios and “replicating” them to a future date. They can then modify the potential scenario, but by using the historical as a template, the user avoids retyping many details such as product assortment

The system may also provide further information, such as a list of top performing items based on both observed and expected values which may be queried by selecting button 436.

The system may also allow the user to export both past and future scheduled promotions as a data file, e.g. to transmit to third parties or facilitate use with third-party software products by selecting button 432.

By selecting button 408, the user may schedule an additional promotion, which will then appear in timeline 404. Timeline 404 may comprise visual cues, such as color, shading or symbols, to draw the user's immediate attention to various features of an event or scenario, such as a promotion. For example, visual cue table 416 may show various cues corresponding to different promotion types, which may be visible in timeline 404. Advantageously, timeline 404 allows the user to quickly get an overview of a variety of scheduled promotions; this may be particularly insightful where the scheduled promotions belong to the same product group. The user will thus be able to more easily comprehend which promotions are concurrently running, whether there are promotions with competing or conflicting goals, and to what extent promotions overlap in time. By being able to immediately see, and re-calculate, information related to the promotions, the user may more easily by able to manage multiple promotions, and handle cross-effects, such as synergies (one promotion advantageously affecting another) or cannibalism (one promotion detrimentally affecting another).

Lift distribution button 428 and corresponding lift distribution graph 430 may additionally assist the user in comparing and determining the expected effectiveness of various parameters, e.g. different promotions. As illustrated, the various types of promotion (free-standing insert promotion, display promotion, etc.) are displayed on common chart that is scaled appropriately to facilitate comparison. Lift distribution selector 432 may allow the user to determine whether lift distribution graph 430 should be displayed in units of money (e.g. dollars) or in units of sold units.

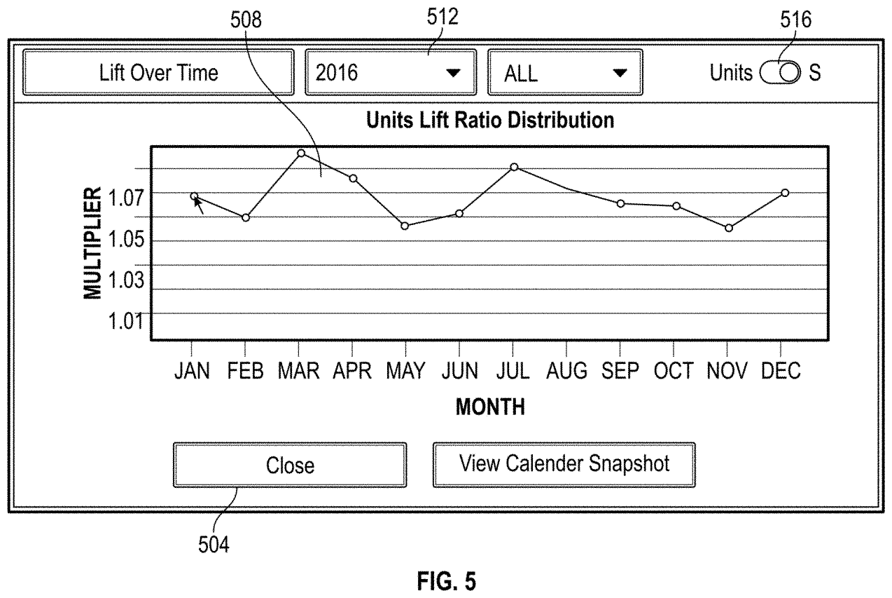

By selecting button 488, the user may calculate a graph of the expected lift over time. Such a graph is illustrated in FIG. 5. Graph 508 shows a time-series of points corresponding to different lift ratios, with linear interpolation between the points. It will be appreciated that graph 508 may comprise observed (e.g. historic) and estimated (e.g. data generated from the statistical or machine learning model). By utilizing selection box 512, the user may specify a time period, for which data is either retrieved or generated to update the graph. By selecting button 504, the user may dismiss graph 508 and return to the previous page of the user interface.

FIG. 6 illustrates an example of an input table 600, as may be generated by data acquisition engine 116. Input table 600 may comprise various entries, wherein each entries describes an association of one or more rows or values (e.g. an integer value, a Boolean value, or a floating-point value) with a key (e.g. a column header, such as a string). Each row may correspond to a specific event or observation, such as a specific sales promotion. As illustrated, integer data entry 604 associates the key “EndMonth” with the value 12, indicating that a specific sales promotion ends in the month of December. Similarly, fractional data entry 616 associates the key “Discount” for a given promotion with the fractional value 50%, and data entry 624 associates the key “Units Sold” with the indicated value.

For some observations or data items on which statistical regression is to be performed by model generation engine 128, the representation of the data may be converted or changed to better fit the statistical model used. This transformation or conversion of data may be described as a transformation or conversion to a canonical or normalized form of the data, and may be performed as part of block 208 as discussed with reference to FIG. 2.

For example, some data may describe an attribute that may be in one of several categories. For example, in the context of a promotion of goods, a promotion may be advertised to the consumer as a percentage discount (e.g. “20% off”), a quantity discount (“buy 2 items, receive a 3^{rd} item for free), or another type of discount. Such a range of values may commonly be encoded as a coded value, such as an integer, where each integer corresponds to a category. To facilitate statistical regression by model generation engine 128, such a coded input value may be decoded to yield an expanded set of values wherein one is true for a given coded input value. This may be accomplished by, for example, use of a one-hot encoding. A one-hot encoding may be a data conversion where a data type that can take N different values is converted into a sequence of N Boolean (e.g. true or false) values with 1 out of the N Boolean values taking on the value true. In another embodiment, one-hot encoding may also be performed by binning or rounding input values (e.g. a floating-point input value) to fall into one of several ranges (e.g. non-overlapping integer ranges).

As illustrated, the one-hot encoding may also be performed by creating a column or key for each possible input value, and assigning 0 or 1 depending on whether a specific input value matches the column or key. For example, one-hot coded columns 626a, 626b and 626c may correspond to a single input value “DiscountType”. The single input value may hold either of values “BuyXGetY”, “Xoff”, or “Other”. One of hot-coded columns 626a, 626b and 626c may be assigned a value of “1” (e.g. hot-coded column 626a may be assigned 1 if the input value holds “BuyXGetY”), whereas the remaining hot-coded columns may be assigned 0.

Similar representations may be used for data items that correspond to flags, bit-fields or other types of coded data wherein one data item describes a plurality of true-false values, as illustrated with respect to flag columns 612a, 612b, 612c and 612d. For example, a bit field may be supplied to the system wherein the least significant bit (e.g. the left-most bit) corresponds to whether a given entity A (e.g. store A) participated in a given event. The next bit may correspond to whether entity B (e.g. store B), participated in the given event, etc. Such a representation of data may be difficult to use with some regression models, since the use of a single variable to store or describe multiple observations may make inference, especially inference based on linear algorithms such as Generalized Linear Regression, more difficult. Advantageously, the system may convert such flags or bit-fields into a series of separate truth values. For example, the system may use bit-wise operations (e.g. bit-wise XOR 2\hat{ }N) to selectively retrieve the Nth flag or value in the bit field, and store it in a separate column, such as flag columns 612a, 612b, 612c and 612d. This may allow the regression algorithm to separately perform regression on the N values.

Advantageously, this representation of input values, including categorical values, may allow more efficient use of regression models, including linear regression models, principal component analysis, etc.

In some embodiments, the system may provide automatic or manual updates or re-calculation of quantities, such as lift quantities, expected values, etc. Automatic updating may be triggered on a periodic schedule (e.g. daily, weekly, or monthly), or based on new data becoming available. Advantageously, the system may retain a dependency graph for each calculated value, wherein upon data being changed, all dependent values are automatically recalculated. For example, the machine learning or statistical regression model used may change as additional information gets assimilated into the model through the training process. This may allow the system to recalculate values that were previously determined using that model with greater confidence.

Updated information may be provided via notifications or reports that are automatically transmitted to a device operated by the user associated with a corresponding trigger. The report and/or notification can be transmitted at the time that the report and/or notification is generated or at some determined time after generation of the report and/or notification. When received by the device, the notification and/or reports can cause the device to display the notification and/or reports via the activation of an application on the device (e.g., a browser, a mobile application, etc.). For example, receipt of the notification and/or reports may automatically activate an application on the device, such as a messaging application (e.g., SMS or MMS messaging application), a standalone application (e.g., a designated report viewing application), or a browser, for example, and display information included in the report and/or notification. If the device is offline when the report and/or notification is transmitted, the application may be automatically activated when the device is online such that the report and/or notification is displayed. As another example, receipt of the report and/or notification may cause a browser to open and be redirected to a login page generated by the system so that the user can log in to the system and view the report and/or notification. Alternatively, the report and/or notification may include a URL of a webpage (or other online information) associated with the report and/or notification, such that when the device (e.g., a mobile device) receives the report, a browser (or other application) is automatically activated and the URL included in the report and/or notification is accessed via the Internet. In an embodiment, access to the report and/or notification may be controlled or restricted by an authentication scheme, for example to restrict access to authenticated users possessing a security clearance specific to the report and/or notification.

### EXAMPLE EMBODIMENTS

The following illustrate some examples of embodiments described herein. This list is for illustration purposes only and should not be construed as an exhaustive list.

In a 1st example embodiment, a computer-implemented method for predicting one or more expected quantities using a machine learning model, the method comprising: accessing a set of data items, wherein each data item is associated with a respective one or more characteristics; generating or training a machine learning model using the set of data items and associated characteristics; receiving one or more sets of simulation parameters from a user, wherein each set of simulation parameters indicates a respective hypothetical scenario including a respective time period; generating user interface data useable for rendering a user interface, the user interface including: a first portion showing a time-based chart including, for each set of simulation parameters, a corresponding timeline indicating the respective time periods associated with the sets of simulation parameters; for each set of simulation parameters received: applying the machine learning model to the set of simulation parameters to predict a set of expected quantities based on the simulation parameters; aggregating one or more types of expected quantities from the set of expected quantities to determine one or more combined quantities; including, in a second portion of the user interface, indications of the one or more combined quantities; and causing the user interface to be presented.

In a 2nd example embodiment, the computer-implemented method of example embodiment 1, wherein accessing the set of data items comprises: retrieving one or more discrete events from a data source, and converting the one or more discrete events into one or more continuous quantities.

In a 3rd example embodiment, the computer-implemented method of example embodiment 2, wherein converting the one or more discrete events into one or more continuous quantities comprises fitting the discrete events to a statistical distribution and choosing a granularity that minimizes a quantity of the resulting distribution associated with error.

In a 4th example embodiment, the computer-implemented method of example embodiment 3, wherein the quantity of the resulting distribution is Mean Integrated Squared Error (MISE).

In a 5th example embodiment, the computer-implemented method of any of example embodiments 1-4, wherein converting the one or more discrete events into one or more continuous quantities comprises averaging quantities from the one or more discrete events.

In a 6th example embodiment, the computer-implemented method of any of example embodiments 1-5, wherein the time-based chart comprises visual cues to indicate one or more parameters associated with each set of simulation parameters.

In a 7th example embodiment, the computer-implemented method of any of example embodiments 1-6, further comprising: receiving observation data; determining a conformity value between the machine learning model and the observation data; causing the conformity value to be presented in the user interface;

In an 8th example embodiment, the computer-implemented method of any of example embodiments 1-7, wherein at least one of the combined quantities is calculated based on a combination of a first quantity from the set of expected quantities and a second quantity from the set of data items.

In a 9th example embodiment, the computer-implemented method of any of example embodiments 1-8, wherein the time-based chart further comprises indications of one at least one of the following: a price, a promotion type, a discount amount.

In a 10th example embodiment, the computer-implemented method of any of example embodiments 1-9, where the time-based chart further comprises at least one indication of a historic set of parameters.

In a 11th example embodiment, the computer-implemented method of any of example embodiments 1-10, wherein the time-based chart is associated with a third portion of the user interface comprising a text interface, wherein a selection by the user of a set of a set of parameters in the time-based chart causes information to be presented in the text interface.

In a 12th example embodiment, the computer-implemented method of example embodiment 11, wherein, for at least one type of output presented in the text interface, at least some observed data is presented in a portion of the text interface if a set of parameters in the past is in the selection and at least some expected data is presented in the portion of the text interface if a set of parameters in the future is in the selection.

In a 13th example embodiment, the computer-implemented method of any of example embodiments 1-12, wherein the machine learning model comprises a fitting to a Poisson distribution.

In a 14th example embodiment, the computer-implemented method of any of example embodiments 1-13, wherein the machine-learning model comprises applying a Generalized Linear Model.

In a 15th example embodiment, the computer-implemented method of any of example embodiments 1-14, wherein the set of expected quantities comprise at least one of the following: units sold, sales revenue, lift.

In a 16th example embodiment, the computer-implemented method of any of example embodiments 1-15, wherein a combined quantity in the set of combined quantities is determined based on a combination of a quantity in the set of expected quantities against a historic baseline.

In a 17th example embodiment, the computer-implemented method of example embodiment 16, wherein the historic baseline is determined based on an average of data items in the set of data items.

In an 18th example embodiment, a computer-implemented method for predicting one or more expected quantities using a machine learning model, the method comprising: accessing a set of data items, wherein each data item is associated with a respective one or more characteristics; generating or training a machine learning model using the set of data items and associated characteristics; receiving a time period and a target parameter from a user, wherein the target parameter indicates a variable with respect to which optimization should be performed; generating candidate sets of simulation parameters; for each candidate set of simulation parameters generated: applying the machine learning model to the set of candidate simulation parameters to predict a set of expected quantities based on the candidate simulation parameters; sorting the set of expected quantities by the target parameter to yield a sorted set of expected quantities; aggregating one or more types of expected quantities from the sorted set of expected quantities to determine one or more combined quantities; including, in a second portion of the user interface, indications of the one or more combined quantities; generating user interface data useable for rendering a user interface, the user interface including the sorted set of expected quantities and candidate simulation parameters; and causing the user interface to be presented.

In a 19th example embodiment, the computer-implemented method of example embodiment 18, further comprising eliminating at least one set of candidate simulation parameters from an end of the sorted set of expected quantities.

In a 20th example embodiment, a computing system configured to predict one or more expected quantities using a machine learning model, the computing system comprising: a computer readable storage medium having program instructions embodied therewith; and one or more processors configured to execute the program instructions to cause the one or more processors to: access a set of data items, wherein each data item is associated with a respective one or more characteristics; generate or training a machine learning model using the set of data items and associated characteristics; receive one or more sets of simulation parameters from a user, wherein each set of simulation parameters indicates a respective hypothetical scenario including a respective time period; generate user interface data useable for rendering a user interface, the user interface including: a first portion showing a time-based chart including, for each set of simulation parameters, a corresponding timeline indicating the respective time periods associated with the sets of simulation parameters; for each set of simulation parameters received: apply the machine learning model to the set of simulation parameters to predict a set of expected quantities based on the simulation parameters; aggregate one or more types of expected quantities from the set of expected quantities to determine one or more combined quantities; include, in a second portion of the user interface, indications of the one or more combined quantities; and cause the user interface to be presented.

In a 21st example embodiment, the computing system of example embodiment 20, wherein accessing the set of data items comprises: retrieving one or more discrete events from a data source; and converting the one or more discrete events into one or more continuous quantities.

In a 22nd example embodiment, the computing system of any of example embodiments 20-21, wherein converting the one or more discrete events into one or more continuous quantities comprises fitting the discrete events to a statistical distribution and choosing a granularity that minimizes a quantity of the resulting distribution associated with error.

Various combinations of the above and below recited features, embodiments and aspects are also disclosed and contemplated by the present disclosure.

In various embodiments, systems and/or computer systems are disclosed that comprise a computer readable storage medium having program instructions embodied therewith, and one or more processors configured to execute the program instructions to cause the one or more processors to perform operations comprising one or more aspects of the above- and/or below-described embodiments (including one or more aspects of the appended claims).

In various embodiments, computer-implemented methods are disclosed in which, by one or more processors executing program instructions, one or more aspects of the above- and/or below-described embodiments (including one or more aspects of the appended claims) are implemented and/or performed.

In various embodiments, computer program products comprising a computer readable storage medium are disclosed, wherein the computer readable storage medium has program instructions embodied therewith, the program instructions executable by one or more processors to cause the one or more processors to perform operations comprising one or more aspects of the above- and/or below-described embodiments (including one or more aspects of the appended claims).

### Additional Implementation Details and Embodiments

Various advantages may be provided by embodiments of the present disclosure. Event data, together with one or more associated quantities, may be retrieved in either discrete-quantity or continuous (e.g. flow or rate-of-change quantity) formats, and may be converted into a continuous representation by the system. Machine learning or statistical inference modeling may then be used to model the event data and various expected quantities associated with the event data. The model may then be queried with parameters corresponding to a hypothetical (e.g. future scenario) to simulate or predict expected quantities associated with that scenario. The model may also be queried with observed data to determine a level of agreement or confidence between the observed data and the model. This may be used to determine whether the observed data significantly deviates from what would be expected based on the model. User interfaces may present the observed data, the predicted expected quantities, and associated time ranges; advantageously, this may allow the user to utilize a common interface to view, access, and query predictions or simulations of future or hypothetical scenarios and records corresponding to historical scenarios. Advantageously, the user interface may also provide the user with a scheduling interface to schedule the actual realization of scenarios that were predicted or simulated.

Various embodiments of the present disclosure may be a system, a method, and/or a computer program product at any possible technical detail level of integration. The computer program product may include a computer readable storage medium (or mediums) having computer readable program instructions thereon for causing a processor to carry out aspects of the present disclosure.

For example, the functionality described herein may be performed as software instructions are executed by, and/or in response to software instructions being executed by, one or more hardware processors and/or any other suitable computing devices. The software instructions and/or other executable code may be read from a computer readable storage medium (or mediums).

The computer readable storage medium can be a tangible device that can retain and store data and/or instructions for use by an instruction execution device. The computer readable storage medium may be, for example, but is not limited to, an electronic storage device (including any volatile and/or non-volatile electronic storage devices), a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a solid state drive, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions (as also referred to herein as, for example, “code,” “instructions,” “module,” “application,” “software application,” and/or the like) for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. Computer readable program instructions may be callable from other instructions or from itself, and/or may be invoked in response to detected events or interrupts. Computer readable program instructions configured for execution on computing devices may be provided on a computer readable storage medium, and/or as a digital download (and may be originally stored in a compressed or installable format that requires installation, decompression or decryption prior to execution) that may then be stored on a computer readable storage medium. Such computer readable program instructions may be stored, partially or fully, on a memory device (e.g., a computer readable storage medium) of the executing computing device, for execution by the computing device. The computer readable program instructions may execute entirely on a user's computer (e.g., the executing computing device), partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart(s) and/or block diagram(s) block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks. For example, the instructions may initially be carried on a magnetic disk or solid state drive of a remote computer. The remote computer may load the instructions and/or modules into its dynamic memory and send the instructions over a telephone, cable, or optical line using a modem. A modem local to a server computing system may receive the data on the telephone/cable/optical line and use a converter device including the appropriate circuitry to place the data on a bus. The bus may carry the data to a memory, from which a processor may retrieve and execute the instructions. The instructions received by the memory may optionally be stored on a storage device (e.g., a solid state drive) either before or after execution by the computer processor.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. In addition, certain blocks may be omitted in some implementations. The methods and processes described herein are also not limited to any particular sequence, and the blocks or states relating thereto can be performed in other sequences that are appropriate.

It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions. For example, any of the processes, methods, algorithms, elements, blocks, applications, or other functionality (or portions of functionality) described in the preceding sections may be embodied in, and/or fully or partially automated via, electronic hardware such application-specific processors (e.g., application-specific integrated circuits (ASICs)), programmable processors (e.g., field programmable gate arrays (FPGAs)), application-specific circuitry, and/or the like (any of which may also combine custom hard-wired logic, logic circuits, ASICs, FPGAs, etc. with custom programming/execution of software instructions to accomplish the techniques).

Any of the above-mentioned processors, and/or devices incorporating any of the above-mentioned processors, may be referred to herein as, for example, “computers,” “computer devices,” “computing devices,” “hardware computing devices,” “hardware processors,” “processing units,” and/or the like. Computing devices of the above-embodiments may generally (but not necessarily) be controlled and/or coordinated by operating system software, such as Mac OS, iOS, Android, Chrome OS, Windows OS (e.g., Windows XP, Windows Vista, Windows 7, Windows 8, Windows 10, Windows Server, etc.), Windows CE, Unix, Linux, SunOS, Solaris, Blackberry OS, VxWorks, or other suitable operating systems. In other embodiments, the computing devices may be controlled by a proprietary operating system. Conventional operating systems control and schedule computer processes for execution, perform memory management, provide file system, networking, I/O services, and provide a user interface functionality, such as a graphical user interface (“GUI”), among other things.

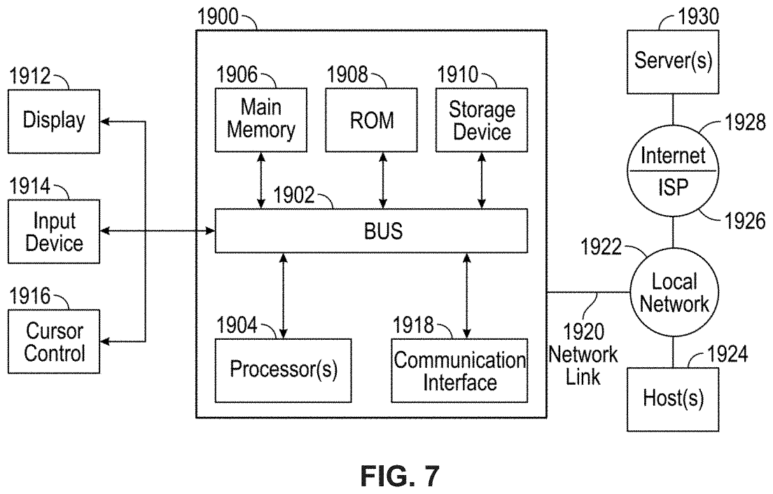

For example, FIG. 7 is a block diagram that illustrates a computer system 1900 upon which various embodiments may be implemented; for example, system 132, or various aspects of it, including user interface engine 120, prediction engine 124 and model generation engine 128, may be implemented on computer system 1900. Computer system 1900 includes a bus 1902 or other communication mechanism for communicating information, and a hardware processor, or multiple processors, 1904 coupled with bus 1902 for processing information. Hardware processor(s) 1904 may be, for example, one or more general purpose microprocessors.

Computer system 1900 also includes a main memory 1906, such as a random access memory (RAM), cache and/or other dynamic storage devices, coupled to bus 1902 for storing information and instructions to be executed by processor 1904. Main memory 1906 also may be used for storing temporary variables or other intermediate information during execution of instructions to be executed by processor 1904. Such instructions, when stored in storage media accessible to processor 1904, render computer system 1900 into a special-purpose machine that is customized to perform the operations specified in the instructions.

Computer system 1900 further includes a read only memory (ROM) 1908 or other static storage device coupled to bus 1902 for storing static information and instructions for processor 1904. A storage device 1910, such as a magnetic disk, optical disk, or USB thumb drive (Flash drive), etc., is provided and coupled to bus 1902 for storing information and instructions.

Computer system 1900 may be coupled via bus 1902 to a display 1912, such as a cathode ray tube (CRT) or LCD display (or touch screen), for displaying information to a computer user. An input device 1914, including alphanumeric and other keys, is coupled to bus 1902 for communicating information and command selections to processor 1904. Another type of user input device is cursor control 1916, such as a mouse, a trackball, or cursor direction keys for communicating direction information and command selections to processor 1904 and for controlling cursor movement on display 1912. This input device typically has two degrees of freedom in two axes, a first axis (e.g., x) and a second axis (e.g., y), that allows the device to specify positions in a plane. In some embodiments, the same direction information and command selections as cursor control may be implemented via receiving touches on a touch screen without a cursor.

Computing system 1900 may include a user interface module to implement a GUI that may be stored in a mass storage device as computer executable program instructions that are executed by the computing device(s). Computer system 1900 may further, as described below, implement the techniques described herein using customized hard-wired logic, one or more ASICs or FPGAs, firmware and/or program logic which in combination with the computer system causes or programs computer system 1900 to be a special-purpose machine. According to one embodiment, the techniques herein are performed by computer system 1900 in response to processor(s) 1904 executing one or more sequences of one or more computer readable program instructions contained in main memory 1906. Such instructions may be read into main memory 1906 from another storage medium, such as storage device 1910. Execution of the sequences of instructions contained in main memory 1906 causes processor(s) 1904 to perform the process steps described herein. In alternative embodiments, hard-wired circuitry may be used in place of or in combination with software instructions.

Various forms of computer readable storage media may be involved in carrying one or more sequences of one or more computer readable program instructions to processor 1904 for execution. For example, the instructions may initially be carried on a magnetic disk or solid state drive of a remote computer. The remote computer can load the instructions into its dynamic memory and send the instructions over a telephone line using a modem. A modem local to computer system 1900 can receive the data on the telephone line and use an infra-red transmitter to convert the data to an infra-red signal. An infra-red detector can receive the data carried in the infra-red signal and appropriate circuitry can place the data on bus 1902. Bus 1902 carries the data to main memory 1906, from which processor 1904 retrieves and executes the instructions. The instructions received by main memory 1906 may optionally be stored on storage device 1910 either before or after execution by processor 1904.

Computer system 1900 also includes a communication interface 1918 coupled to bus 1902. Communication interface 1918 provides a two-way data communication coupling to a network link 1920 that is connected to a local network 1922. For example, communication interface 1918 may be an integrated services digital network (ISDN) card, cable modem, satellite modem, or a modem to provide a data communication connection to a corresponding type of telephone line. As another example, communication interface 1918 may be a local area network (LAN) card to provide a data communication connection to a compatible LAN (or WAN component to communicated with a WAN). Wireless links may also be implemented. In any such implementation, communication interface 1918 sends and receives electrical, electromagnetic or optical signals that carry digital data streams representing various types of information.

Network link 1920 typically provides data communication through one or more networks to other data devices. For example, network link 1920 may provide a connection through local network 1922 to a host computer 1924 or to data equipment operated by an Internet Service Provider (ISP) 1926. ISP 1926 in turn provides data communication services through the world wide packet data communication network now commonly referred to as the “Internet” 1928. Local network 1922 and Internet 1928 both use electrical, electromagnetic or optical signals that carry digital data streams. The signals through the various networks and the signals on network link 1920 and through communication interface 1918, which carry the digital data to and from computer system 1900, are example forms of transmission media.

Computer system 1900 can send messages and receive data, including program code, through the network(s), network link 1920 and communication interface 1918. In the Internet example, a server 1930 might transmit a requested code for an application program through Internet 1928, ISP 1926, local network 1922 and communication interface 1918.

The received code may be executed by processor 1904 as it is received, and/or stored in storage device 1910, or other non-volatile storage for later execution.

As described above, in various embodiments certain functionality may be accessible by a user through a web-based viewer (such as a web browser), or other suitable software program). In such implementations, the user interface may be generated by a server computing system and transmitted to a web browser of the user (e.g., running on the user's computing system). Alternatively, data (e.g., user interface data) necessary for generating the user interface may be provided by the server computing system to the browser, where the user interface may be generated (e.g., the user interface data may be executed by a browser accessing a web service and may be configured to render the user interfaces based on the user interface data). The user may then interact with the user interface through the web-browser. User interfaces of certain implementations may be accessible through one or more dedicated software applications. In certain embodiments, one or more of the computing devices and/or systems of the disclosure may include mobile computing devices, and user interfaces may be accessible through such mobile computing devices (for example, smartphones and/or tablets).

Many variations and modifications may be made to the above-described embodiments, the elements of which are to be understood as being among other acceptable examples. All such modifications and variations are intended to be included herein within the scope of this disclosure. The foregoing description details certain embodiments. It will be appreciated, however, that no matter how detailed the foregoing appears in text, the systems and methods can be practiced in many ways. As is also stated above, it should be noted that the use of particular terminology when describing certain features or aspects of the systems and methods should not be taken to imply that the terminology is being re-defined herein to be restricted to including any specific characteristics of the features or aspects of the systems and methods with which that terminology is associated.

Conditional language, such as, among others, “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

The term “substantially” when used in conjunction with the term “real-time” forms a phrase that will be readily understood by a person of ordinary skill in the art. For example, it is readily understood that such language will include speeds in which no or little delay or waiting is discernible, or where such delay is sufficiently short so as not to be disruptive, irritating, or otherwise vexing to a user.

Conjunctive language such as the phrase “at least one of X, Y, and Z,” or “at least one of X, Y, or Z,” unless specifically stated otherwise, is to be understood with the context as used in general to convey that an item, term, etc. may be either X, Y, or Z, or a combination thereof. For example, the term “or” is used in its inclusive sense (and not in its exclusive sense) so that when used, for example, to connect a list of elements, the term “or” means one, some, or all of the elements in the list. Thus, such conjunctive language is not generally intended to imply that certain embodiments require at least one of X, at least one of Y, and at least one of Z to each be present.

The term “a” as used herein should be given an inclusive rather than exclusive interpretation. For example, unless specifically noted, the term “a” should not be understood to mean “exactly one” or “one and only one”; instead, the term “a” means “one or more” or “at least one,” whether used in the claims or elsewhere in the specification and regardless of uses of quantifiers such as “at least one,” “one or more,” or “a plurality” elsewhere in the claims or specification.

The term “comprising” as used herein should be given an inclusive rather than exclusive interpretation. For example, a general purpose computer comprising one or more processors should not be interpreted as excluding other computer components, and may possibly include such components as memory, input/output devices, and/or network interfaces, among others.

While the above detailed description has shown, described, and pointed out novel features as applied to various embodiments, it may be understood that various omissions, substitutions, and changes in the form and details of the devices or processes illustrated may be made without departing from the spirit of the disclosure. As may be recognized, certain embodiments of the inventions described herein may be embodied within a form that does not provide all of the features and benefits set forth herein, as some features may be used or practiced separately from others. The scope of certain inventions disclosed herein is indicated by the appended claims rather than by the foregoing description. All changes which come within the meaning and range of equivalency of the claims are to be embraced within their scope.

What is claimed is:

1. A computer-implemented method for predicting one or more expected outcomes using a machine learning model, the method comprising:
accessing a set of data items, wherein each data item is associated with a respective one or more characteristics;
generating or training a machine learning model using the set of data items and associated characteristics;
receiving a set of simulation parameters from a user, wherein the set of simulation parameters includes one or more items of information associated with an event;
filling in or supplementing the set of simulation parameters with simulation parameters not specified by the user; and
applying the machine learning model to the set of simulation parameters, including the filled in or supplemented simulation parameters, to generate an expected outcome based on the set of simulation parameters.

2. The computer-implemented method of claim 1, wherein the one or more characteristics include at least one of: type of event, time of event, date of event, location of event, amount of transaction, quantity of transaction, location of transaction, person associated with transaction, category of transaction, terms or conditions of transaction, temperature, altitude, meteorological conditions, load, or output.

3. The computer-implemented method of claim 1, wherein the one or more characteristics include at least one of: type of event, time of event, date of event, location of event, amount of transaction, quantity of transaction, location of transaction, person associated with transaction, category of transaction, terms or conditions of transaction, temperature, altitude, meteorological conditions, load, or output.

4. The computer-implemented method of claim 1, wherein filling in or supplementing the set of simulation parameters comprises determining an average, from past events, of an unspecified item of information.

5. The computer-implemented method of claim 1, wherein filling in or supplementing the set of simulation parameters comprises determining a minimum, from past events, of an unspecified item of information.

6. The computer-implemented method of claim 1, wherein filling in or supplementing the set of simulation parameters comprises determining a maximum, from past events, of an unspecified item of information.

7. The computer-implemented method of claim 1, wherein filling in or supplementing the set of simulation parameters comprises determining an aggregate, from past events, of an unspecified item of information.

8. The computer-implemented method of claim 1 further comprising:
applying the machine learning model to a subset of the set of simulation parameters to generate baseline outcome; and
generating a comparison between the expected outcome and the baseline outcome.

9. The computer-implemented method of claim 1 further comprising:
aggregating one or more expected values of the expected outcome;
applying the machine learning model to a subset of the set of simulation parameters to generate baseline outcome;
aggregating one or more expected values of the baseline outcome; and
generating a comparison between the aggregated expected values of the expected outcome and the aggregated expected values of the baseline outcome.

10. The computer-implemented method of claim 9, wherein aggregating comprises at least one of: determining an average, determining a minimum, determining a maximum, or determining a median.

11. A computing system configured to predict one or more expected outcomes using a machine learning model, the computing system comprising:
a computer readable storage medium having program instructions embodied therewith; and
one or more processors configured to execute the program instructions to cause the one or more processors to:
access a set of data items, wherein each data item is associated with a respective one or more characteristics;
generate or training a machine learning model using the set of data items and associated characteristics;
receive a set of simulation parameters from a user, wherein the set of simulation parameters includes one or more items of information associated with an event;
fill in or supplement the set of simulation parameters with simulation parameters not specified by the user; and
apply the machine learning model to the set of simulation parameters, including the filled in or supplemented simulation parameters, to generate an expected outcome based on the set of simulation parameters.

12. The computing system of claim 11, wherein the one or more characteristics include at least one of: type of event, time of event, date of event, location of event, amount of transaction, quantity of transaction, location of transaction, person associated with transaction, category of transaction, terms or conditions of transaction, temperature, altitude, meteorological conditions, load, or output.

13. The computing system of claim 11, wherein the one or more characteristics include at least one of: type of event, time of event, date of event, location of event, amount of transaction, quantity of transaction, location of transaction, person associated with transaction, category of transaction, terms or conditions of transaction, temperature, altitude, meteorological conditions, load, or output.

14. The computing system of claim 11, wherein filling in or supplementing the set of simulation parameters comprises determining an average, from past events, of an unspecified item of information.

15. The computing system of claim 11, wherein filling in or supplementing the set of simulation parameters comprises determining a minimum, from past events, of an unspecified item of information.

16. The computing system of claim 11, wherein filling in or supplementing the set of simulation parameters comprises determining a maximum, from past events, of an unspecified item of information.

17. The computing system of claim 11, wherein filling in or supplementing the set of simulation parameters comprises determining an aggregate, from past events, of an unspecified item of information.

18. The computing system of claim 11, wherein the one or more processors are configured to execute the program instructions to further cause the one or more processors to:
apply the machine learning model to a subset of the set of simulation parameters to generate baseline outcome; and
generate a comparison between the expected outcome and the baseline outcome.

19. The computing system of claim 11, wherein the one or more processors are configured to execute the program instructions to further cause the one or more processors to:
aggregate one or more expected values of the expected outcome;
apply the machine learning model to a subset of the set of simulation parameters to generate baseline outcome;
aggregate one or more expected values of the baseline outcome; and
generate a comparison between the aggregated expected values of the expected outcome and the aggregated expected values of the baseline outcome.

20. The computing system of claim 11, wherein aggregating comprises at least one of: determining an average, determining a minimum, determining a maximum, or determining a median.
